(19) United States
(12) Patent Application Publication
(10) Pub. No.: US 2022/0267210 A1
(43) Pub. Date: Aug. 25, 2022

(54) SOLID COMPOSITION

(71) Applicant: Sumitomo Chemical Company, Limited, Chuo-ku, Tokyo (JP)

(72) Inventors: Atsunori DOI, Tsukuba-shi (JP); Satoshi SHIMANO, Tsukuba-shi, Ibaraki (JP)

(21) Appl. No.: 17/625,230

(22) PCT Filed: Jun. 22, 2020
(86) PCT No.: PCT/JP2020/024355

§ 371 Date: Jan. 6, 2022

(30) Foreign Application Priority Data
Jul. 12, 2019 (JP) 2019-130451

(51) Int. Cl. C04B 14/30; C04B 28/26; C09C 1/36; C09C 3/04

(52) U.S. Cl. CPC C04B 14/305; C04B 28/26; C09C 1/36; C09C 3/041; C01P 2006/32; C01P 2002/77; C01P 2006/17

(57) ABSTRACT

A solid composition contains a first material and a powder and satisfies requirements 1 and 2. Requirement 1: |dA(T)/dT| satisfies 10 ppm/° C. or more at least at −200° C. to 1,200° C. A is (an a-axis lattice constant of a crystal in the powder)/(a c-axis lattice constant of a crystal in the powder), obtained from X-ray diffractometry of the powder. Requirement 2: C is 0.04 or more. C is (a log differential pore volume when a pore diameter of the solid composition is B in a pore distribution curve of the solid composition)/(a log differential pore volume corresponding to a maximum peak intensity in the pore distribution curve of the solid composition). B is (a pore diameter giving a maximum peak intensity in the pore distribution curve of the solid composition)/2. The pore distribution curve of the solid composition shows a relationship between the pore diameter and the log differential pore volume.

### TECHNICAL FIELD

The present invention relates to a solid composition.

### BACKGROUND ART

Conventionally, it is known to add a solid material having a negative linear thermal expansion coefficient to a solid material having a positive linear thermal expansion coefficient to reduce the linear thermal expansion coefficient of the solid material.

For example, Patent Document 1 discloses that zirconium tungstate having a negative linear thermal expansion coefficient is added to copper or a copper alloy having a positive linear thermal expansion coefficient to reduce the linear thermal expansion coefficient of a material used for a heat sink for an electronic device.

### PRIOR ART DOCUMENTS

### Patent Documents

Patent Document 1: JP-A-2017-8337

### SUMMARY OF THE INVENTION

### Problems to be Solved by the Invention

However, the linear thermal expansion coefficient of the conventional material is not necessarily sufficiently lowered.

The present invention has been made in view of the above problems, and an object thereof is to provide a novel solid composition capable of sufficiently reducing the linear thermal expansion coefficient.

### Means for Solving the Problems

As a result of various studies, the present inventors have reached the present invention. That is, the present invention provides the following invention.

A first solid composition according to the present invention contains a first material and a powder, and satisfies the following requirements 1 and 2.

Requirement 1: |dA(T)/dT| satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: C is 0.04 or more.

C is (a log differential pore volume when a pore diameter of the solid composition is B in a pore distribution curve of the solid composition)/(a log differential pore volume corresponding to a maximum peak intensity in the pore distribution curve of the solid composition).

B is (a pore diameter giving a maximum peak intensity in the pore distribution curve of the solid composition)/2. The pore distribution curve of the solid composition is measured by mercury porosimetry, and shows a relationship between the pore diameter and the log differential pore volume of the solid composition.

Here, the powder may be a metal oxide powder.

The metal oxide powder may be a metal oxide powder containing a metal having d electrons.

The metal oxide powder may be a metal oxide powder containing titanium.

The metal oxide powder containing titanium may be a TiOₓ (x=1.30 to 1.66) powder.

The content of the powder may be 5 wt % or more and 95 wt % or less.

The first material may be at least one selected from the group consisting of a resin, an alkali metal silicate, a ceramic, and a metal.

A second solid composition according to the present invention is a solid composition containing a first material and a powder, and satisfies the following requirements 1 and 3.

Requirement 1: |dA(T)/dT| satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 3: a cumulative pore volume of pores having a pore diameter of 0.3 to 1.5 μm in the solid composition measured by mercury porosimetry is 0.005 (mL/g) or more.

Here, the powder may be a metal oxide powder.

The metal oxide powder may be a metal oxide powder containing a metal having d electrons.

The metal oxide powder may be a metal oxide powder containing titanium.

The metal oxide powder containing titanium may be a TiOₓ (x=1.30 to 1.66) powder.

The content of the powder may be 5 wt % or more and 95 wt % or less.

The first material may be at least one selected from the group consisting of a resin, an alkali metal silicate, a ceramic, and a metal.

### Effect of the Invention

According to the present invention, it is possible to provide a solid composition capable of sufficiently reducing the linear thermal expansion coefficient.

### BRIEF DESCRIPTION OF THE DRAWINGS

FIG. 1 is a graph showing a relationship between the a-axis length/c-axis length and the temperature T of the powder of Example 1, that is, A(T).

### MODE FOR CARRYING OUT THE INVENTION

### <Solid Composition According to First Embodiment>

The solid composition according to the first embodiment includes a first material and a powder, and satisfies the following requirements 1 and 2.

Requirement 1: |dA(T)/dT| satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: C is 0.04 or more.

C is (a log differential pore volume when a pore diameter of the solid composition is B in a pore distribution curve of the solid composition)/(a log differential pore volume corresponding to a maximum peak intensity in the pore distribution curve of the solid composition).

B is (a pore diameter giving a maximum peak intensity in the pore distribution curve of the solid composition)/2. The pore distribution curve of the solid composition is measured by mercury porosimetry, and shows a relationship between the pore diameter and the log differential pore volume of the solid composition. The unit of the log differential pore volume can be, for example, mL/g.

### [Powder]

The powder of the present embodiment satisfies the above requirement 1.

The lattice constant in the definition of A is specified by powder X-ray diffractometry. As an analysis method, there are a Rietveld method and an analysis by fitting by a least-squares method.

In the present specification, in the crystal structure specified by powder X-ray diffractometry, an axis corresponding to the smallest lattice constant is defined as an a-axis, and an axis corresponding to the largest lattice constant is defined as a c-axis. The length of the a-axis and the length of the c-axis of the crystal lattice are defined as an a-axis length and a c-axis length, respectively.

A(T) is a parameter indicating the magnitude of anisotropy of the length of the crystal axis, and is the function of a temperature T (unit: ° C.). A larger value of A(T) indicates that the a-axis length is larger relative to the c-axis length, and a smaller value of A indicates that the a-axis length is smaller relative to the c-axis length.

Here, |dA(T)/dT| represents the absolute value of dA(T)/dT, and dA(T)/dT represents the differential of A(T) by T (temperature).

Here, in the present specification, |dA(T)/dT| is defined by the following equation.

|dA(T)/dT|=|A(T+50)−A(T)|/50 (D)

As described above, the powder according to the present embodiment needs to satisfy |dA(T)/dT| of 10 ppm/° C. or more at at least one temperature T1 in a range of −200° C. to 1,200° C. Note that |dA(T)/dT| is defined within a range where the powder exists in a solid state.

Therefore, the maximum temperature of T in the equation (D) is up to a temperature 50° C. lower than the melting point of the powder. That is, when the limitation “at least one temperature T1 in a range of −200° C. to 1,200° C.” is added, the temperature range of T in the equation (D) is −200 to 1,150° C.

Preferably, |dA(T)/dT| is preferably 20 ppm/° C. or more, and more preferably 30 ppm/° C. or more at at least one temperature T1 in a range of −200° C. to 1,200° C. The upper limit of |dA(T)/dT| is preferably 1,000 ppm/° C. or less, and more preferably 500 ppm/° C. or less.

The fact that the value of |dA(T)/dT| is 10 ppm/° C. or more at the at least one temperature T1 means that the change in anisotropy of the crystal structure associated with the temperature change is large.

At the at least one temperature T1, dA(T)/dT may be positive or negative, but is preferably negative.

Depending on the type of crystal in the powder, there is a powder whose crystal structure changes due to structural phase transition in a certain temperature range. In the present specification, in a crystal structure at a certain temperature, an axis having the largest crystal lattice constant is defined as a c-axis, and an axis having the smallest crystal lattice constant is defined as an a-axis. In any of the triclinic system, monoclinic system, orthorhombic system, tetragonal system, hexagonal system, and rhombohedral system, the a-axis and the c-axis are defined as described above.

The powder is preferably an oxide powder. In particular, the powder is more preferably a metal oxide powder. The metal oxide powder may contain a plurality of types of metals.

The metal oxide powder is not particularly limited, but is preferably a metal oxide powder containing a metal having d electrons, and more preferably a metal oxide powder containing a metal having only 3d electrons among d electrons.

The metal oxide powder containing a metal having d electrons is not particularly limited, and examples thereof include metal oxide powders containing Sc, Ti, V, Cr, Mn, Fe, Co, Ni, Cu, Y, Zr, Nb, and Mo.

Examples of the metal oxide powder containing a metal having only 3d electrons among d electrons include metal oxide powders containing Sc, Ti, V, Cr, Mn, Fe, Co, Ni, and Cu. Among them, a metal oxide powder containing titanium is preferable from the viewpoint of the resource.

More specifically, the metal oxide powder containing titanium is preferably a powder represented by a composition formula TiOₓ (x=1.30 to 1.66), and more preferably a powder represented by a composition formula TiOₓ (x=1.40 to 1.60). In TiOₓ, some of Ti atoms may be substituted with another element.

The metal oxide powder containing titanium may be an oxide powder containing titanium and metal atoms other than titanium, such as LaTiO₃, in addition to the TiOₓ powder.

The crystal structure of the particles constituting the powder preferably has a perovskite structure or a corundum structure, and more preferably has a corundum structure.

The crystal system is not particularly limited, but is preferably a rhombohedral system. The space group is preferably attributed to R-3c.

When the powder is a metal oxide powder, |dA(T)/dT| at −200° C. to 1,200° C. is 10 ppm/° C. or more at at least one temperature.

When the powder is a metal oxide powder containing a metal having d electrons, |dA(T)/dT| at −100° C. to 1,000° C. is preferably 10 ppm/° C. or more at at least one temperature.

When the powder is a metal oxide powder containing a metal having only 3d electrons among d electrons, |dA(T)/dT| at −100° C. to 800° C. is preferably 10 ppm/° C. or more at at least one temperature.

When the powder is TiOₓ (x=1.30 to 1.66), |dA(T)/dT| at 0° C. to 500° C. is preferably 10 ppm/° C. or more at at least one temperature.

The particle diameter of the powder is not particularly limited, but D50 in volume-based particle diameter distribution in laser diffraction particle diameter distribution measurement can be about 0.5 to 100 μm.

### [First Material]

The first material is not particularly limited, and examples thereof include resins, alkali metal silicates, ceramics, and metals. The first material may be a binder material which binds the powders or a matrix material which holds the powders in a dispersed state.

Examples of the resin include thermoplastic resins and thermosetting resins.

Examples of the thermosetting resin include epoxy resin, oxetane resin, unsaturated polyester resin, alkyd resin, phenol resin (novolac resin, resol resin, etc.), acrylic resin, urethane resin, silicone resin, polyimide resin, and melamine resin.

Examples of the thermoplastic resin are polyolefin (polyethylene, polypropylene, etc.), ABS resin, polyamide (nylon 6, nylon 6,6, etc.), polyamide imide, polyester (polyethylene terephthalate, polyethylene naphthalate), liquid crystalline resin, polyphenylene ether, polyacetal, polycarbonate, polyphenylene sulfide, polyimide, polyetherimide, polyether sulfone, polyketone, polystyrene, and polyetheretherketone.

The first material may contain one type of the resin or two or more types of the resins.

The first material is preferably epoxy resin, polyether sulfone, a liquid crystal polymer, polyimide, polyamide imide, or silicone from the viewpoint of being able to enhance heat resistance.

Examples of the alkali metal silicate include lithium silicate, sodium silicate, and potassium silicate. The first material may contain one type of alkali metal silicate or two or more types of alkali metal silicates. These materials are preferable because they have high heat resistance.

The ceramic is not particularly limited, and examples include ceramics such as alumina, silica (silicon oxide and silica glass), titania, zirconia, magnesia, ceria, yttria, oxide-based ceramics such as zinc oxide and iron oxide; nitride-based ceramics such as silicon nitride, titanium nitride, and boron nitride; silicon carbide, calcium carbonate, aluminum sulfate, barium sulfate, aluminum hydroxide, potassium titanate, talc, kaolin clay, kaolinite, halloysite, pyrophyllite, montmorillonite, sericite, mica, amesite, bentonite, asbestos, zeolite, calcium silicate, magnesium silicate, diatomaceous earth, and silica sand. The first material may contain one type of ceramic or two or more types of ceramics.

Ceramics are preferable because they can increase heat resistance. A sintered body can be produced by spark plasma sintering or the like.

The metal is not particularly limited, and examples thereof include elementary metals such as aluminum, tantalum, niobium, titanium, molybdenum, iron, nickel, cobalt, chromium, copper, silver, gold, platinum, lead, tin, and tungsten, alloys such as stainless steel (SUS), and mixtures thereof. The first material may contain one type of metal or two or more types of metals. Such metals are preferable because they can increase heat resistance.

### [Other Components]

The composition of the present embodiment may contain other components other than the first material and the powder.

Examples thereof include a catalyst. The catalyst is not particularly limited, and examples thereof include acidic compounds, alkaline compounds, and organic metallic compounds. As the acidic compound, acids such as hydrochloric acid, sulfuric acid, nitric acid, phosphoric acid, phosphoric acid, formic acid, acetic acid, and oxalic acid can be used. As the alkaline compound, ammonium hydroxide, tetramethylammonium hydroxide, tetraethylammonium hydroxide, or the like can be used. Examples of the organic metallic compound catalyst include those containing aluminum, zirconium, tin, titanium, and zinc.

### [Weight Ratio of Each Component]

The content of the powder in the solid composition may be 1 wt % or more, 3 wt % or more, 5 wt % or more, 10 wt % or more, 20 wt % or more, 40 wt % or more, or 70 wt % or more from the viewpoint of sufficiently obtaining the effect of reducing the linear thermal expansion coefficient. The content of the powder in the solid composition may be 99 wt % or less, 95 wt % or less, or 90 wt % or less.

The content of the first material in the solid composition may be 1 wt % or more, 5 wt % or more, or 10 wt % or more. The content of the first material in the solid composition may be 99 wt % or less, 97 wt % or less, 95 wt % or less, 90 wt % or less, 80 wt % or less, 60 wt % or less, or 30 wt % or less.

### [Pore Distribution of Solid Composition]

The pore structure of the solid composition according to the present embodiment satisfies the above requirement 2.

Requirement 2: C is 0.04 or more.

C is (a log differential pore volume when the pore diameter of the solid composition is B in the pore distribution curve of the solid composition)/(a log differential pore volume corresponding to the maximum peak intensity in the pore distribution curve of the solid composition)

B is (a pore diameter giving the maximum peak intensity in the pore distribution curve of the solid composition)/2

The pore distribution curve of the solid composition is measured by mercury porosimetry, and shows the relationship between the pore diameter and the log differential pore volume of the solid composition.

The value of C is a parameter related to the distribution of pore diameters of the solid composition. A larger value of C indicates a wider distribution of pore diameters, and a smaller value of C indicates a narrower distribution of pore diameters.

In the solid composition of the present embodiment, the value of the parameter C is preferably 0.04 or more and 0.60 or less, and more preferably 0.04 or more and 0.50 or less.

The range of B is not particularly limited, but may be 0.1 to 10 μm.

The value of the log differential pore volume of the peak in the pore distribution curve is also not particularly limited, but can be set to 0.02 to 2 mL/g.

The present inventors have found that, in a solid composition containing a powder satisfying the requirement 1, that is, a powder in which the size of the crystal lattice is largely and anisotropically changed according to a temperature change, when the solid composition has a pore distribution where the value of the parameter C is larger than 0.04, a large effect of reducing the linear thermal expansion coefficient is exhibited.

As a means for obtaining such a pore structure, for example, it may be possible to obtain the pore structure by performing a heat treatment at a temperature exceeding 300° C.

### <Solid Composition According to Second Embodiment>

Next, a solid composition according to a second embodiment will be described. In the present embodiment, only differences from the first embodiment will be described, and the description of the same points as the first embodiment will be omitted.

The solid composition of the present embodiment satisfies the requirement 3 instead of the requirement 2.

Requirement 3: the cumulative pore volume of pores having a pore diameter of 0.3 to 1.5 μm in the solid composition measured by mercury porosimetry is 0.005 (mL/g) or more.

Preferably, this cumulative pore volume is 0.006 to 0.30 (mL/g), more preferably 0.007 to 0.30 (mL/g), and still more preferably 0.010 to 0.30 (mL/g).

The present inventors have found that, in a solid composition containing a powder satisfying the requirement 1, that is, a powder in which the size of the crystal lattice is greatly and anisotropically changed according to a temperature change, when the cumulative pore volume of pores having a pore diameter of 0.3 to 1.5 μm measured by mercury porosimetry is in this range, a large effect of reducing the linear thermal expansion coefficient is exhibited.

The solid composition according to the present embodiment does not need to satisfy the requirement 2 described above, but may satisfy the requirement 2.

According to the solid composition according to the two embodiments of the present invention, the linear thermal expansion coefficient of the member using the solid composition can be sufficiently lowered. Therefore, it is possible to obtain a member having an extremely small dimensional change when the temperature changes. Therefore, the solid composition can be suitably used for an optical member or a semiconductor manufacturing equipment member which is particularly sensitive to a dimensional change due to temperature.

In addition, according to the solid composition according to the present embodiment, a solid material having a negative linear thermal expansion coefficient can also be obtained. Having a negative linear thermal expansion coefficient means that the volume contracts with heating. In a plate in which an end surface of a plate made of another material having a positive linear thermal expansion coefficient is bonded to an end surface (side surface) of a plate made of a solid composition having a negative linear thermal expansion coefficient, the linear thermal expansion coefficient in a direction orthogonal to the thickness direction in the entire plate can be made substantially zero. The linear thermal expansion coefficient of the solid composition can be adjusted by selecting a combination of the powder and the first material, adjusting the concentration of the powder in the solid composition, adjusting the void structure, and the like.

In addition, when such a solid composition is used as a sealing member of an electronic device or a coating material for a substrate or the like, a difference between the linear thermal expansion coefficient of the electronic device or the substrate and the linear thermal expansion coefficient of the sealing member or the coating material can be reduced. As a result, cracks and peeling of the sealing member or the coating material caused by heat generation of the electronic device or the substrate can be suppressed.

### <Method for Producing Solid Composition>

The method for producing the solid composition is not particularly limited.

For example, a powder and a raw material of the first material are mixed to obtain a mixture, and then the raw material of the first material in the mixture is converted into the first material, whereby a solid composition in which the powder and the first material are combined can be produced.

For example, when the first material is a resin or an alkali metal silicate, a mixture containing a solvent, a resin or an alkali metal silicate, and a powder is prepared, and the solvent is removed from the mixture, whereby a solid composition containing the powder and the first material can be obtained. As a method of removing the solvent, a method of evaporating the solvent by natural drying, vacuum drying, heating, or the like can be applied. From the viewpoint of suppressing generation of coarse bubbles, when removing the solvent, it is preferable to remove the solvent while maintaining the temperature of the mixture at a temperature equal to or lower than the boiling point of the solvent.

When the first material is a resin, the solvent is, for example, an organic solvent such as an alcohol solvent, an ether solvent, a ketone solvent, a glycol solvent, a hydrocarbon solvent, or an aprotic polar solvent, or water. The solvent in the case of an alkali metal silicate is, for example, water.

When the resin is a curable resin, it is preferable to perform a crosslinking treatment of the resin in the mixture after removing the solvent. Specifically, the mixture from which the solvent has been removed may be heated to a temperature equal to or higher than the boiling point of the solvent, or the mixture from which the solvent has been removed may be irradiated with energy rays such as ultraviolet rays. In the case of an alkali metal silicate, a curing treatment may be performed by further heating the mixture after removing the solvent.

When the first material is a ceramic or a metal, a mixture of a raw material powder of the first material and a powder is prepared, and the mixture is heat-treated to sinter the raw material powder of the first material, whereby a solid composition containing the first material and the powder as a sintered body can be obtained. The pores of the solid composition can be adjusted as necessary by a heat treatment such as annealing. As the sintering method, methods such as normal heating, hot pressing, and spark plasma sintering can be employed.

In the spark plasma sintering, a pulsed current is applied to the mixture of the raw material powder of the first material and the powder while the mixture is pressurized. As a result, electric discharge occurs between the raw material powders of the first material, so that the raw material powders of the first material can be heated and sintered.

The plasma sintering step is preferably performed under an inert atmosphere such as argon, nitrogen, or vacuum in order to prevent the resulting compound from being deteriorated by contact with air.

The pressure applied in the plasma sintering step is preferably in a range of more than 0 MPa and 100 MPa or less. In order to obtain a high-density first material, the pressure applied in the plasma sintering step is preferably 10 MPa or more, and more preferably 30 MPa or more.

The heating temperature in the plasma sintering step is preferably sufficiently lower than the melting point of the first material as an object.

The mixture is applied onto a substrate and then the solvent is removed or sintering is performed, whereby a sheet-like solid composition can be obtained. In addition, the mixture is supplied to a mold and then the solvent is removed or sintering is performed, whereby a solid composition having an optional shape corresponding to the shape of the mold can be obtained.

Furthermore, the size and distribution of pores can be adjusted by a heat treatment of the resulting solid composition.

One method of adjusting the size and distribution in the pore distribution is to change the particle diameter distribution of the powder.

### EXAMPLES

Hereinafter, the present invention will be described in more detail with reference to Examples.

### 1. Crystal Structure Analysis of Powder

As the analysis of the crystal structure, a powder was subjected to powder X-ray diffractometry at different temperatures under the following conditions using a powder X-ray diffractometer SmartLab (manufactured by Rigaku Corporation) to obtain a powder X-ray diffraction pattern. The lattice constant was refined based on the obtained pattern by the least-squares method using PDXL2 software (manufactured by Rigaku Corporation), and two lattice constants, that is, the a-axis length and the c-axis length were obtained.

Measuring apparatus: powder X-ray diffractometer SmartLab (manufactured by Rigaku Corporation) X-ray generator: CuKα radiation source voltage 45 kV, current 200 mA

Slit: slit width 2 mm

Scan step: 0.02 deg

Scan range: 5 to 80 deg

Scan speed: 10 deg/min

X-ray detector: one-dimensional semiconductor detector

Measurement atmosphere: Ar 100 mL/min

Sample stage: dedicated glass substrate made of SiO₂

### 2. Mercury Porosimetry

The pore distribution of the solid composition was measured by the following method.

Pretreatment: the solid composition was dried under vacuum at 120° C. for 4 hours.

Measurement: the pore diameter was calculated by mercury porosimetry using the following Washburn equation.

PD=−4σ COS θ Washburn equation:

P; pressure, σ; surface tension of mercury, D; pore diameter, θ; contact angle between mercury and sample

Measurement condition: surface tension of mercury: 480 dynes/cm

Contact angle between mercury and sample: 140 degrees

Measuring apparatus: AutoPore IV9520 (manufactured by micrometrics Instrument Corporation)

### 3. Measurement of Linear Thermal Expansion Coefficient

The linear thermal expansion coefficient of the solid composition was measured using the following apparatus.

Measuring apparatus: Thermo plus EVO2, TMA series, Thermo plus 8310

The temperature range was set to 25° C. to −320° C., and the value of the linear thermal expansion coefficient at 190 to 210° C. was calculated as a representative value.

Reference solid: alumina

The typical size of the measurement sample of the solid composition was 15 mm×4 mm×4 mm.

The sample length L(T) at the temperature T was measured assuming that the longest side of the solid composition with a size of 15 mm×4 mm×4 mm was defined as the sample length L. The dimensional change rate ΔL(T)/L(30° C.) with respect to the sample length at 30° C. (L(30° C.)) was calculated by the following equation.

ΔL(T)/L(30° C.)=(L(T)−L(30° C.))/L(30° C.)

In this example, the dimensional change rate ΔL(T)/L(30° C.) was obtained at each temperature of 190° C. and 210° C., and the linear thermal expansion coefficient α (1/° C.) at 190° C. to 210° C. was calculated by the following equation.

α(1/° C.)=(ΔL(210° C.)−ΔL(190° C.))/(L(30° C.)×20° C.)

### EXAMPLES

### Production of Solid Composition

### Example 1

As a powder, a Ti₂O₃ powder (150 μm Pass, purity 99.9%, manufactured by Kojundo Chemical Laboratory Co., Ltd.) was used.

As a raw material of the first material, sodium silicate No. 1 (aqueous sodium silicate solution) manufactured by Fuji Chemical Co., Ltd. was used. The solid content in sodium silicate No. 1 manufactured by Fuji Chemical Co., Ltd. is about 55 wt %.

Water was used as an additional solvent.

Then, 1.00 g of the powder, 0.25 g of the raw material of the first material, and 0.06 g of the solvent were added and mixed to obtain a mixture.

The resulting mixture was placed in a mold made of polytetrafluoroethylene and cured with the following curing profile.

The temperature was raised to 80° C. in 15 minutes, held at 80° C. for 20 minutes, then raised to 150° C. in 20 minutes, and held at 150° C. for 60 minutes.

Further, a treatment of raising the temperature to 320° C., holding the temperature for 10 minutes, and lowering the temperature was then performed to obtain a solid composition of Example 1 from the above steps.

### Example 2

A Ti₂O₃ powder (150 μm Pass, purity 99.9%, manufactured by Kojundo Chemical Laboratory Co., Ltd.) was pulverized by a bead mill under the following conditions to obtain a powder.

Pulverization conditions: a batch-type ready mill (RM B-08) manufactured by AIMEX Co., Ltd. was used as a bead mill. Pulverization was performed using a 800 cm³ vessel under conditions of 1,348 rpm and a peripheral speed of 5 m/s. ZrO₂ beads having a particle diameter of 1 mm were used, 217 g of water, 613 g of ZrO₂, and Ti₂O₃ (150 μm Pass, 24.9 g, manufactured by Kojundo Chemical Laboratory Co., Ltd.) were mixed, and pulverization was performed for 10 minutes.

A solid composition of Example 2 was prepared by the same method as in Example 1 except for using the powder described above.

### Example 3

A Ti₂O₃ powder (150 μm Pass, purity 99.9%, manufactured by Kojundo Chemical Laboratory Co., Ltd.) was pulverized by a bead mill under the following conditions to obtain a powder.

Pulverization conditions: a batch-type ready mill (RM B-08) manufactured by AIMEX Co., Ltd. was used as a bead mill. Pulverization was performed using a 800 cm³ vessel under conditions of 1,348 rpm and a peripheral speed of 5 m/s. ZrO₂ beads having a particle diameter of 1 mm were used, 217 g of water, 613 g of ZrO₂, and Ti₂O₃ (150 μm Pass, 24.9 g, manufactured by Kojundo Chemical Laboratory Co., Ltd.) were mixed, and pulverization was performed for 20 minutes.

A solid composition of Example 3 was prepared by the same method as in Example 1 except for using the powder described above.

### Comparative Example 1

A Ti₂O₃ powder (150 μm Pass, purity 99.9%, manufactured by Kojundo Chemical Laboratory Co., Ltd.) was pulverized by a bead mill under the following conditions to obtain a powder.

Pulverization conditions: a batch-type ready mill (RM B-08) manufactured by AIMEX Co., Ltd. was used as a bead mill. Pulverization was performed using a 800 cm³ vessel under conditions of 1,348 rpm and a peripheral speed of 5 m/s. ZrO₂ beads having a particle diameter of 1 mm were used, 217.0 g of water, 707.9 g of ZrO₂, and Ti₂O₃ (150 μm Pass, 49.9 g, manufactured by Kojundo Chemical Laboratory Co., Ltd.) were mixed, and pulverization was performed for 60 minutes.

A solid composition of Comparative Example 1 was prepared by the same method as in Example 1 except for using the powder described above.

[Temperature Dependency Change of a-Axis Length and c-Axis Length]

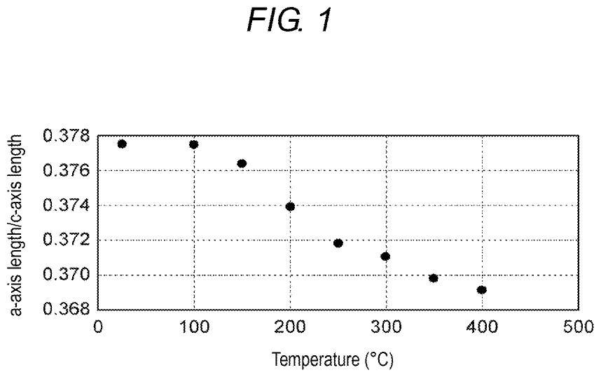

The powder of Example 1 was subjected to X-ray diffractometry at 25° C., 100° C., 150° C., 200° C., 250° C., 300° C., 350° C., and 400° C. As a result, the powder of Example 1 was attributed to Ti₂O₃ having a corundum structure, and the space group was R-3c. The a-axis length, the c-axis length, and the a-axis length/c-axis length of the powder of Example 1 at each of the above temperatures are summarized in Table 1. FIG. 1 shows a relationship between the a-axis length/c-axis length and the temperature T in Example 1, that is, A(T). In addition, dA(T)/dT=(A(T+50)−A(T))/50 was −49 ppm/° C., and |dA(T)/dT| was 49 ppm/° C. at a temperature T1 of 150° C.

TABLE 1

| | | | a-axis length/ |
|---|---|---|---|
| Temperature | a-axis length | c-axis length | c-axis length |
| (° C.) | (Å) | (Å) | (—) |
| 25 | 5.151 | 13.645 | 0.378 |
| 100 | 5.151 | 13.647 | 0.377 |
| 150 | 5.148 | 13.677 | 0.376 |
| 200 | 5.137 | 13.737 | 0.374 |
| 250 | 5.132 | 13.802 | 0.372 |
| 300 | 5.127 | 13.816 | 0.371 |
| 350 | 5.125 | 13.857 | 0.370 |
| 400 | 5.123 | 13.877 | 0.369 |

The powder of Example 2 was subjected to X-ray diffractometry at 150° C. and 200° C., respectively. As a result, the powder of Example 2 was attributed to Ti₂O₃ having a corundum structure, and the space group was R-3c. At a temperature T of 150° C., dA(T)/dT=(A(T+50)−A(T))/50 was −44 ppm/° C. In addition, at a temperature T of 150° C., |dA(T)/dT| was 44 ppm/° C.

The powder of Example 3 was subjected to X-ray diffractometry at 150° C. and 200° C., respectively. As a result, the powder of Example 3 was attributed to Ti₂O₃ having a corundum structure, and the space group was R-3c. At a temperature T of 150° C., dA(T)/dT=(A(T+50)−A(T))/50 was −42 ppm/° C. In addition, at a temperature T of 150° C., |dA(T)/dT| was 42 ppm/° C.

The results of X-ray measurement of Examples 2 and 3 are shown in Table 2.

TABLE 2

| | 150° C. | | 200° C. | |
|---|---|---|---|---|
| | a-axis length | c-axis length | a-axis length | c-axis length |
| | (Å) | (Å) | (Å) | (Å) |
| Example 2 | 5.146 | 13.657 | 5.138 | 13.716 |
| Example 3 | 5.146 | 13.663 | 5.137 | 13.716 |

The powder of Comparative Example 1 was subjected to X-ray diffractometry at 25° C., and the powder was attributed to Ti₂O₃ having a corundum structure, and the space group was R-3c as in Example 1. In Examples 1 to 3, the value of dA(T)/dT does not change so much accompanying pulverization, and it is therefore considered that dA(T)/dT=(A(T+50)−A(T))/50 of the powder of Comparative Example 1 at a temperature T1 of 150° C. is negative, and |dA(T)/dT| is at least 10 ppm/° C. or more.

In Examples 1 to 3 and Comparative Example 1, moisture contained in the raw material of the first material and the solvent added were all evaporated by heating. In Examples 1 to 3 and Comparative Example 1, the concentration of the powder in the resulting solid composition was 88 wt %, and the concentration of the first material (cured product of sodium silicate) was 12 wt %. Note that the above values were calculated by calculating the solid weights of the powder and the first material in the solid composition with the solid content of sodium silicate No. 1 manufactured by Fuji Chemical Co., Ltd. as 55 wt %.

The cross-sectional SEM observation confirmed that there was no pore structure inside each particle of the Ti₂O₃ powder manufactured by Kojundo Chemical Laboratory Co., Ltd. From this, there is no pore structure inside each particle of the powders used in Examples 1 to 3 and Comparative Example 1.

The obtained results of Examples and Comparative Examples are summarized in Table 3.

TABLE 3

| | | | Cumulative | Linear |
|---|---|---|---|---|
| | | | pore volume of | thermal expansion |
| | \|dA(T)/dT\| | | pore diameter of | coefficient at |
| | at 150° C. | C | 0.3 to 1.5 μm | 190° C. to 210° C. |
| | (ppm/° C.) | (—) | (mL/g) | (ppm/° C.) |
| Example 1 | 49 | 0.310 | 0.0154 | −38.0 |
| Example 2 | 44 | 0.059 | 0.1093 | −3.6 |
| Example 3 | 42 | 0.044 | 0.0537 | 1.5 |
| Comparative | — | 0.038 | 0.0007 | 6.7 |
| Example 1 | | | | |

In Examples, the linear thermal expansion coefficient can be made lower than that in Comparative Examples.

1. A solid composition comprising:
a first material; and
a powder, wherein
the solid composition satisfies the following requirements 1 and 2:
requirement 1: |dA(T)/dT| satisfies 10 ppm/° C. or more at at least one temperature T1 in a range of −200° C. to 1,200° C.
where A is (an a-axis (shorter axis) lattice constant of a crystal in the powder)/(a c-axis (longer axis) lattice constant of a crystal in the powder), and each of the lattice constants is obtained from X-ray diffractometry of the powder; and
requirement 2: C is 0.04 or more
where C is (a log differential pore volume when a pore diameter of the solid composition is B in a pore distribution curve of the solid composition)/(a log differential pore volume corresponding to a maximum peak intensity in the pore distribution curve of the solid composition), and
B is (a pore diameter giving a maximum peak intensity in the pore distribution curve of the solid composition)/2; and
the pore distribution curve of the solid composition is measured by mercury porosimetry, and shows a relationship between the pore diameter and the log differential pore volume of the solid composition.

2. The solid composition according to claim 1, wherein the powder is a metal oxide powder.

3. The solid composition according to claim 2, wherein the metal oxide powder is a metal oxide powder containing a metal having d electrons.

4. The solid composition according to claim 2, wherein the metal oxide powder is a metal oxide powder containing titanium.

5. The solid composition according to claim 4, wherein the metal oxide powder containing titanium is a TiOₓ (x=1.30 to 1.66) powder.

6. The solid composition according to claim 1, wherein a content of the powder is 5 wt % or more and 95 wt % or less.

7. The solid composition according to claim 1, wherein the first material is at least one selected from the group consisting of a resin, an alkali metal silicate, a ceramic, and a metal.

8. A solid composition comprising:
a first material; and
a powder, wherein
the solid composition satisfies the following requirements 1 and 3:
requirement 1: |dA(T)/dT| satisfies 10 ppm/° C. or more at at least one temperature T1 in a range of −200° C. to 1,200° C.
where A is (an a-axis (shorter axis) lattice constant of a crystal in the powder)/(a c-axis (longer axis) lattice constant of a crystal in the powder), and each of the lattice constants is obtained from X-ray diffractometry of the powder; and
requirement 3: a cumulative pore volume of pores having a pore diameter of 0.3 to 1.5 μm in the solid composition measured by mercury porosimetry is 0.005 (mL/g) or more.

9. The solid composition according to claim 8, wherein the powder is a metal oxide powder.

10. The solid composition according to claim 9, wherein the metal oxide powder is a metal oxide powder containing a metal having d electrons.

11. The solid composition according to claim 9, wherein the metal oxide powder is a metal oxide powder containing titanium.

12. The solid composition according to claim 11, wherein the metal oxide powder containing titanium is a TiOₓ (x=1.30 to 1.66) powder.

13. The solid composition according to claim 8, wherein a content of the powder is 5 wt % or more and 95 wt % or less.

14. The solid composition according to claim 8, wherein the first material is at least one selected from the group consisting of a resin, an alkali metal silicate, a ceramic, and a metal.
